(19) United States
(12) Patent Application Publication
(10) Pub. No.: US 2010/0124091 A1
(43) Pub. Date: May 20, 2010

(54) Magnetic Data Storage Device and Method

(75) Inventor: Russell Paul Cowburn, London (GB)

Correspondence Address: MCDONNELL BOEHNEN HULBERT & BERGHOFF LLP, 300 S. WACKER DRIVE, 32ND FLOOR, CHICAGO, IL, 60606, US

(73) Assignee: INGENIA HOLDINGS (UK) LIMITED, London (GB)

(21) Appl. No.: 12/618,416

(22) Filed: Nov. 13, 2009

Related U.S. Application Data
(60) Provisional application No. 61/114,318, filed on Nov. 13, 2008.

(30) Foreign Application Priority Data
Nov. 13, 2008 (GB) 0820842.3

(51) Int. Cl. G11C 19/00; H01L 21/00

(52) U.S. Cl. 365/80; 438/3; 257/E21.001

(57) ABSTRACT

A data storage device comprises an array of parallel magnetic nanowires each having a uniaxial anisotropy with an easy axis substantially perpendicular to the longitudinal axis of the nanowire and which is rotated about the longitudinal axis along the length of the nanowire, and a magnetisation state that follows the easy axis, where each nanowire has a data input element for nucleating magnetic domains separated by domain walls in an end of the nanowire, the sequence of domains and walls representing binary data, and a data read-out element operable to detect the magnetisation at an end of the nanowire, the device also comprising a magnetic field source operable to generate a magnetic field rotating in a plane substantially perpendicular to the longitudinal axes of the nanowires so as to propagate domain walls along the at least one nanowire. Reversal of the direction of rotation of the magnetic field reverses the propagation direction of the domain walls, so that data can be moved in either direction along the nanowires.

### BACKGROUND OF THE INVENTION

The present invention relates to a magnetic data storage device and a method for storing data using magnetic nanowires.

Current data storage devices for storing data files (contiguous blocks of data) are typically either hard disk drives or non-volatile semiconductor memory such as Flash memory. Non-volatile semiconductor devices are attractive because they are compact and fast, and unlike hard disk drives, have no moving parts. However, the cost-per-bit for semiconductor storage is presently about 100 times higher than for hard disk storage, making the latter still popular. A major advance in the speed and portability of data storage could occur if a non-volatile solid-state memory (hence having no moving parts) could be fabricated with 10 to 100 times the storage density of current solid-state devices but at the same cost. This combination of features would allow hard disk storage to be replaced by solid-state storage.

The currently known limits of the lithographic techniques used to fabricate solid state devices indicate that it is not going to be feasible to make devices in which each memory cell has an area 10-100 times less than present sizes. A potential solution to this is to make three-dimensional solid-state data storage devices. Each memory cell retains the same size footprint as current devices, so that no advance in lithography is required, and an increase in storage density is achieved by stacking multiple storage elements on top of one another.

Advocates of such an approach agree that it is only economic if the electronics for reading and writing the data bits to and from the storage remain in a single layer within the device. A shift register is therefore required to move the bits to and from the read-write layer through the other layers. Hence, any such device desirably has the ability to pump data sequentially from one storage cell to another as simply as possible. This allows data to be injected at one level, perhaps the lowest level in the stack, moved to higher levels for storage, and later retrieved by pumping it back to the bottom layer or up to the top layer to be read.

The storage and shifting of data in magnetic nanowires has been proposed as a suitable technique for three-dimensional data storage. Cowburn et al [1, 2, 3, 4] propose networks of logic elements formed from magnetic nanowires. A substrate carries a number of logic elements, and several substrates can be stacked together. The nanowires are arranged in chains of cusps, and data, encoded by the state of magnetic domains and/or the domain walls therebetween formed in the nanowires, is moved along the wires using a rotating magnetic field.

Parkin et al propose [5, 6, 7, 8, 9, 10] an alternative technique using straight nanowires in which pulses of spin-polarised electrical current move domain walls through the nanowire using the spin-momentum-transfer effect.

Both these schemes have disadvantages. In Cowburn's arrangement, the achievable data storage density is limited by the size of the cusps in the nanowires. Parkin's approach suffers from a difficulty in isolating neighbouring data bits from one another, because they all move together asynchronously. Any minor defects in the fabrication of the nanowire can lead to collision of bits, and subsequent loss of data. Also, the spin polarised current densities necessary to move domain walls under spin-momentum transfer are high, leading to unwanted heat dissipation.

Hence, alternative proposals for three-dimensional solid-state data storage are desirable.

### SUMMARY OF THE INVENTION

A first aspect of the present invention is directed to a data storage device comprising: at least one nanowire of magnetic material having a uniaxial anisotropy with an easy axis substantially perpendicular to the longitudinal axis of the nanowire and which is rotated about the longitudinal axis along the length of the nanowire; each of the at least one nanowires having associated therewith: a data input element operable to nucleate magnetic domains in an end of the nanowire, the domains separated by domain walls substantially perpendicular to the longitudinal axis of the nanowire; and a data read-out element operable to detect the magnetisation at an end of the nanowire; and a magnetic field source operable to generate a rotating magnetic field over the length of the at least one nanowire, the magnetic field rotating in a plane substantially perpendicular to the longitudinal axis of the at least one nanowire so as to propagate domain walls along the at least one nanowire.

The specified anisotropy and magnetisation state form a spiral path within the nanowire. In conjunction with the appropriately oriented rotating magnetic field, this allows magnetic domain walls of both positive and negative magnetic charge to be propagated in the same direction along the nanowire. Thus, a sequence of data bits can be represented in the nanowire by the domains and/or the domains walls between the domains, and successfully propagated along the nanowire without any distortion. In this manner, a known problem with domain wall propagation in nanowires, whereby an externally applied magnetic field aligned along the length of a nanowire will move positive and negative domain walls in opposite directions and thus corrupt a stored data sequence, is addressed.

In some embodiments, the magnetisation state follows the easy axis except if a domain wall is present. Thus it will be understood that the magnetisation state can be transitioned at a domain wall, where the magnetisation state is forced not to follow the easy axis.

In some embodiments, the magnetic field source is arranged to match the rotation sense of the rotating magnetic field to the rotation sense of locus of the easy axis of the anisotropy.

In some embodiments, the at least one nanowire comprises a plurality of nanowires with parallel longitudinal axes. This extends the invention to offer a three-dimensional data storage device with the desirable characteristic of the data input and output components being able to be confined to one or two planes in the device. Data can be input at first ends of the plurality of wires, stacked up within the individual nanowires, and moved to one or other end of the wires to be read out. The ability to correctly propagate data along the spiral path of the anisotropy offers a simple mechanism for moving data up and down within in a three-dimensional device. High data storage densities can be achieved in this manner, rivalling or exceeding current capacities of hard disk drives and non-volatile semiconductor memory.

A three-dimensional configuration may be achieved, for example, if each nanowire comprises a pillar of magnetic material upstanding from a substrate. Each data input element may then comprise a current-carrying electrode interposed between the pillar and the substrate.

Alternatively, each nanowire may comprise a plug of magnetic material in a pore formed in a substrate.

The direction of propagation of the domain walls along the nanowire depends on the direction of rotation of the magnetic field. Thus, it is possible to select at which end of the nanowire the data is read out. For a first-in first-out shift register, each data read-out element is arranged at the opposite end of its associated nanowire to the data input element. The domain walls are propagated right along the nanowire from the first end to the other. Conversely, for a first-in last-out shift register, each data read-out element is arranged at the same end of its associated nanowire as the data input element. The domain walls are thus returned to the first end to be detected for data read-out, by reversing the rotating magnetic field. For this, the magnetic field source may be operable such that the direction of rotation of the magnetic field can be reversed.

Each data input element may be associated with only one nanowire. This allows a different data sequence to be stored in each nanowire, to give the maximum data storage density for a given number of nanowires.

Alternatively, each data input element may be associated with more than one nanowire. A data sequence is thus written and stored simultaneously in several nanowires. This provides a degree of redundancy that may be useful in some cases. Also, the arrangement may be preferred if fabrication alignment limitations make it more convenient to have a one-to-many relationship between the data input elements and the nanowires.

A second aspect of the present invention is directed to a method of storing data, comprising: applying a magnetic field to a first end of a nanowire of magnetic material to nucleate a sequence of magnetic domains separated by domain walls in the end of the nanowire, the sequence being selected to represent a chosen binary bit stream of data, where the nanowire has a uniaxial anisotropy with an easy axis substantially perpendicular to the longitudinal axis of the nanowire and which is rotated about the longitudinal axis along the length of the nanowire; and applying a rotating magnetic field over the length of the nanowire, the magnetic field rotating in a plane substantially perpendicular to the longitudinal axis of the nanowire so as to propagate the domain walls along the nanowire.

The method may further comprise using the rotating magnetic field to propagate the domain walls to the second end of the nanowire; and reading out the bit stream of data by detecting the magnetisation of the second end of the nanowire as the domains and domain walls arrive at the second end. These steps allow data storage in a first-in first-out arrangement.

Alternatively, the method may further comprise reversing the direction of rotation of the rotating magnetic field and using the reversed rotating magnetic field to propagate the domain walls back the first end of the nanowire; and reading out the bit stream of data by detecting the magnetisation of the first end of the nanowire as the domains and domain walls arrive at the first end. These steps allow data storage in a first-in last-out arrangement.

A third aspect of the present invention is directed to a method of fabricating a data storage device, comprising: forming at least one nanowire of magnetic material by depositing magnetic material in or on a substrate so as to create a uniaxial anisotropy in the magnetic material which has an easy axis substantially perpendicular to the longitudinal axis of the nanowire and which is rotated about the longitudinal axis along the length of the nanowire; providing in association with each of the at least one nanowires: a data input element operable to nucleate magnetic domains in an end of the nanowire; and a data read-out element operable to detect the magnetisation at an end of the nanowire; and providing a magnetic field source operable to generate a rotating magnetic field over the length of the at least one nanowire, the magnetic field rotating in a plane substantially perpendicular to the longitudinal axis of the at least one nanowire so as to propagate domain walls along the at least one nanowire.

Each of the at least one nanowires may be formed as a pillar upstanding from the substrate. The anisotropy may be created by depositing the magnetic material on the substrate in the presence of a magnetic field during relative rotation between the substrate and the magnetic field. Alternatively, the anisotropy may be created by depositing the magnetic material from a deposition source onto the substrate at a strong angle from the normal to the substrate surface during relative rotation between the substrate and the deposition source. In the present context, a strong angle is considered to be an angle of at least the order of 45°. Other techniques for creating the required anisotropy may also be employed if desired.

Alternatively, each of the at least one nanowires may be formed as a plug of magnetic material within a pore in the substrate.

### BRIEF DESCRIPTION OF THE DRAWINGS

For a better understanding of the invention and to show how the same may be carried into effect reference is now made by way of example to the accompanying drawings in which:

FIG. 1A shows a schematic representation of a magnetic nanowire encoding binary data bits according to the prior art;

FIG. 1B shows the nanowire of FIG. 1A a short time after application of an external magnetic field;

FIG. 2 shows a schematic representation of a cylindrical magnetic nanowire having a spiral-shaped anisotropy according to an embodiment of the present invention;

FIG. 3 shows the nanowire of FIG. 2 containing magnetic domain walls being propagated by an external rotating magnetic field according to an embodiment of the invention;

FIG. 4A shows a schematic representation of a magnetic nanowire configured as a first-in first-out serial data register according to an embodiment of the invention;

FIG. 4B shows a schematic representation of a magnetic nanowire configured as a first-in last-out serial data register according to a further embodiment;

FIG. 5 shows a perspective view of a data storage device according an embodiment of the invention; and

FIG. 6 shows a cross-sectional view through a data storage device according to an alternative embodiment of the invention.

While the invention is susceptible to various modifications and alternative forms, specific embodiments are shown by way of example in the drawings and are herein described in detail. It should be understood, however, that the drawings and detailed description are not intended to limit the invention to the particular form disclosed, but on the contrary, the invention is to cover all modifications, equivalents and alternatives falling within the spirit and scope of the present invention as defined in the appended claims.

### DETAILED DESCRIPTION

Magnetic data storage techniques for storage of serial data can store and propagate data bits in magnetic nanowires. The geometry of a nanowire formed from magnetic material is such that a sequence of magnetic domains separated by domain walls can be formed in the wire and propagated therealong. The nanowire can therefore be thought of as a domain wall conduit. A domain can be formed by applying a localised magnetic field higher than a threshold value termed the nucleation field, and a domain wall can be moved along the wire by applying a more widespread magnetic field higher than a threshold value termed the propagation field. The nucleation field is higher than the propagation field.

Within a domain, the magnetisation is oriented parallel to the length of the nanowire, and can either be directed along the intended direction of domain propagation, or against this direction. These two magnetisation directions can be used to encode binary data, if one direction (for example, the direction along the propagation direction) is assigned to encode “1” and the other direction is assigned to encode “0”. Thus, if a specified length of nanowire is chosen to correspond to a single bit, the magnetisation in each of many adjacent lengths can be set so as to represent and store a desired binary data sequence. Each time there is a change from “1” to “0” or vice versa between adjacent bits, a magnetic field above the nucleation threshold can be applied to reverse the magnetic field direction. Thus, data can be written into the wire by appropriate switching of a magnetic field source of sufficient strength.

Between each region, or domain, of opposite magnetisation, there is a magnetic domain wall. Note that a single domain can encode more than one data bit if adjacent bits have the same value, since there is no domain wall between such bits. The domain walls carry a magnetic charge, due to the divergence of magnetisation in the wall. The charge depends on the magnetisation direction in the two adjacent domains. If the magnetisation is represented by an arrow indicating the direction, a wall between two arrow heads, called a head-to-head wall, carries a positive magnetic charge because the magnetisation on either side of the wall flows into the wall. Conversely, a tail-to-tail wall, where the magnetisation flows out of the wall, carries a negative charge.

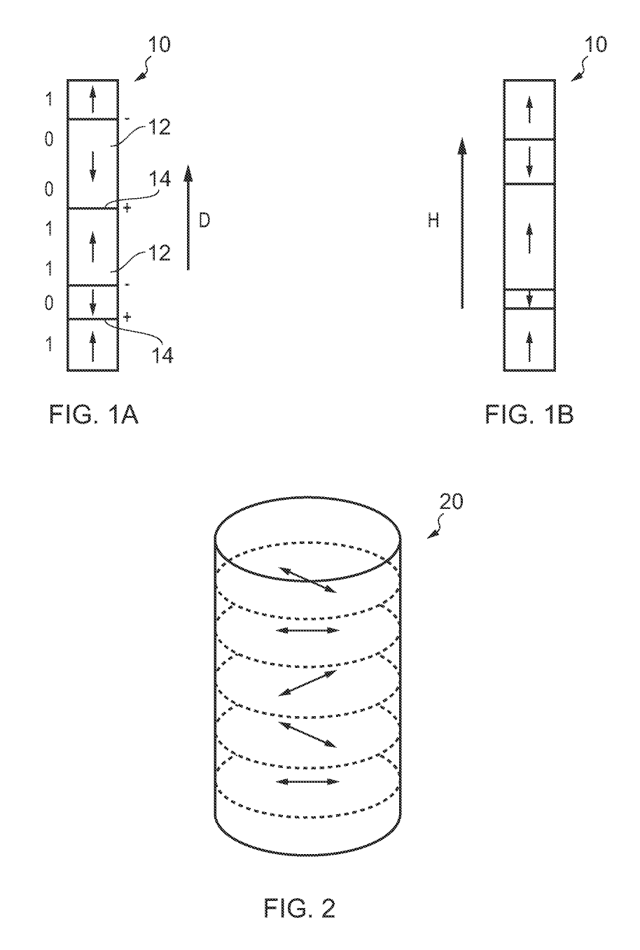

FIG. 1A shows a representation of a section of nanowire 10 in which the data sequence “1011001” has been stored. The small arrows indicate the magnetisation direction in the domains 12, the charge of each domain wall 14 is shown, and the arrow D represents the intended data propagation direction.

The domain walls move under the influence of an applied external magnetic field of a magnitude exceeding the propagation field. Thus, the stored sequence of data bits can be transported along the nanowire, allowing data to be transferred from one location to another, or into and out of a storage device.

However, the charge on the domain walls causes a fundamental problem. A uniform magnetic field causes positive domain walls to move in the direction of the applied field, while negative domain walls are moved in the opposite direction. Basic magnetic topology means that the domain walls in a sequence of domains will alternate in charge. Hence, a uniform magnetic field cannot move all the walls in a nanowire in the same direction. For a field arranged in the intended direction of wall propagation, all the positive walls will move forwards, and the negative walls will move backwards. The effect of this is to expand the domains in which 1s are encoded and to contract and eventually annihilate the domains encoding 0s. At best, the data sequence becomes distorted and corrupted, and at worst data is lost.

FIG. 1B shows the section of nanowire of FIG. 1A shortly after the application of a magnetic field H applied along the intended data propagation direction D. Compared with the original domain sizes as shown in FIG. 1A, the 1 domains have expanded and the 0 domains have shrunk. Since a fixed length of nanowire is intended to encode a single bit, the data sequence has been damaged.

Some proposed schemes for magnetic nanowire data storage use the sign or the chirality of the domain walls to encode binary 1s and 0s, instead of the magnetisation direction of the domains, but this data arrangement still suffers if a linear uniform external magnetic field is applied to move the domain walls.

The disadvantages of the prior art schemes proposed by Cowburn and by Parkin and mentioned in the Background of the Invention arise at least in part from complexities used to address the above problem. The cusp geometry used by Cowburn allows both positive and negative domain walls to be moved in the same direction if the applied magnetic field is rotating, but as mentioned, the cusps limit the available miniaturisation so that data density cannot be greatly increased. In Parkin's system, the spin-polarised electric current moves the domain walls by spin-momentum transfer, which does not depend on the sign of the charge carried by the wall, so that all walls move in the same direction. The movement is asynchronous, however, which produces difficulties in maintaining isolation between adjacent bits of data.

The present invention proposes an alternative solution to the problem of moving positive and negative domain walls in the same direction so that a sequential train of domains and walls encoding a data bit sequence can be propagated along a magnetic nanowire. The proposed arrangement is also suited for use as a three-dimensional data storage device, and offers high data storage density. Spin-momentum transfer is not used, so that the problems suffered by Parkin's arrangement are avoided. Also, the physical geometry is simpler that Cowburn's cusp arrangement.

According to the invention, a nanowire for storing and propagating data bits is fabricated from magnetic material such that the wire has a uniaxial anisotropy with an easy axis which lies in the plane perpendicular to the longitudinal axis of the wire. In addition, the easy axis is rotated in this plane with respect to distance along the wire. The easy axis thus forms a spiral along the length of the wire.

FIG. 2 shows a schematic representation of a cylindrical nanowire 20 having an easy axis of this configuration. A number of planes through the nanowire are illustrated, each perpendicular to the longitudinal axis. The easy axis in each plane is indicated by a double-headed arrow. As can be seen, in each plane the easy axis is rotated with respect to the easy axis in the adjacent planes.

Furthermore, the magnetisation state of the nanowire is arranged so that it follows the easy axis and thus also has a spiral form along the length of the wire. In some cases, this configuration is the simplest magnetisation state (the ground state of the magnetisation energy), so that the magnetisation readily remains in the desired spiral shape. In other cases, the magnetisation spiral may be found not to be the ground state, so that measures should be taken to preserve the spiral form within the nanowire so that it does not collapse into a more energetically favourable configuration.

The effect of this spiralling of the locus of the easy axis of the anisotropy and magnetisation state is that a domain wall within the nanowire cannot be moved along the wire by an applied magnetic field directed along the length of the wire. Instead, however, a rotating magnetic field covering substantially the length of the wire and which rotates in the plane perpendicular to the longitudinal axis of the wire (being the plane occupied by the easy axis at any selected point along the wire) will propagate the domain wall. The wall moves along the length of wire by being “screwed” along the energetic spiral formed by the spiralling locus of the easy axis of the anisotropy. Moreover, domain walls of both positive and negative magnetic charge move in the same direction because the propagation direction is determined by the relative chiralities of the anisotropy spiral and the rotating magnetic field, and not by the absolute direction of the magnetisation.

Consequently, a sequence of domains and domain walls can be propagated correctly and without disturbance along the nanowire. The direction of propagation can be reversed by reversing the direction of rotation of the applied magnetic field. Thus, data can be propagated along the wire in either direction as required.

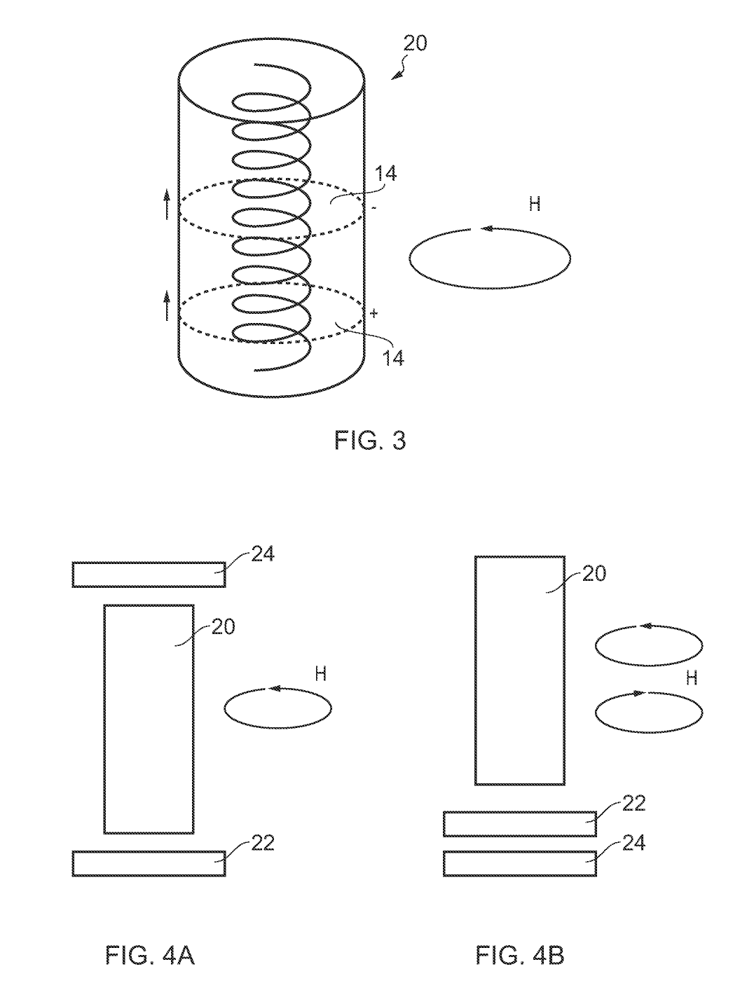

FIG. 3 shows a further schematic representation of the nanowire 20 of FIG. 2. In FIG. 3, the spiralling locus of the easy axis of the anisotropy is indicated, and two domain walls 14 are present, one positive and one negative. Under the influence of an applied rotating magnetic field H, both the domain walls 14 move upwards towards the top end of the wire 20.

As with known magnetic nanowires, a domain wall can be introduced into a nanowire according to embodiments of the present invention by application of a local magnetic field exceeding the nucleation field to force a 180 degree change in the magnetisation direction within the wire. Thus, appropriate modulation of the local field will introduce or “write” a sequence of domains and walls into the wire which encode a desired data bit sequence, where the bits are represented by the walls or by the domains as preferred.

If the local field is applied by a magnetic field source (which can be thought of as a data input element) arranged to form domain walls at a first end of the nanowire, the rotating propagating field can be applied to move the domain walls, and thus the data sequence represented, along the nanowire towards the second end. The data can be retrieved by detecting the magnetisation of the second end of the nanowire (using a magnetic sensor, which can be thought of as a data read-out element) as the domains and walls emerge under the influence of the rotating field. This arrangement produces a first-in first out shift register for data storage. Alternatively, after having been moved into the nanowire for storage, the domain walls can be propagated back to the first end of the wire by reversing the direction of rotation of the magnetic field, and the magnetisation can then be detected at the first end. This provides a first-in last-out shift register.

FIG. 4A shows a highly simplified representation of a nanowire 20 arranged as a first-in first out register. A data input element 22 is positioned adjacent to the first, lower, end of the wire, and is operable to produce a localised magnetic field to generate domain walls by nucleation in the first end of the wire. A further magnetic field source (not shown) generates a rotating magnetic field H with an appropriate rotation direction to move domain walls upwards in the nanowire. A data read-out element 24 positioned adjacent to the second, upper end of the wire 20 is operable to detect the magnetisation of the upper end as the domain walls arrive under the influence of the rotating magnetic field H.

FIG. 4B shows the nanowire 20 arranged instead as a first-in last-out register. In this example, the data read-out element 24 is positioned adjacent to the first end of the wire 20, and the magnetic field source for generating the rotating magnetic field H is operable to generate a field rotating in either direction so that domain walls can be moved both up and down the wire, and hence returned to the first end when it is desired to read the stored data.

The Figures described thus far have shown the nanowire in a form that can be considered as a column or pillar of magnetic material. This provides scope for the desirable implementation of magnetic data storage in a three-dimensional configuration, thereby offering a potential increase in storage density. The ability to screw or wind the data bits up and down a nanowire pillar allows data to be stacked up, and hence provides the capability for transferring data between layers in a vertical stack that is desirable for a three-dimensional device since it allows the data read-in and read-out electronics to be confined to one or two layers in the device.

Therefore, embodiments of the invention relate to data storage devices in which a plurality of nanowires having a spiral anisotropy are arranged together as adjacent pillars or columns. By positioning the nanowires with their longitudinal axes substantially parallel, a single external rotating magnetic field can be applied to move the domain walls in all the nanowires. If preferred, however, the rotating field could be limited to a subset of the nanowires at any one time, or several fields could be applied together to cover all the nanowires.

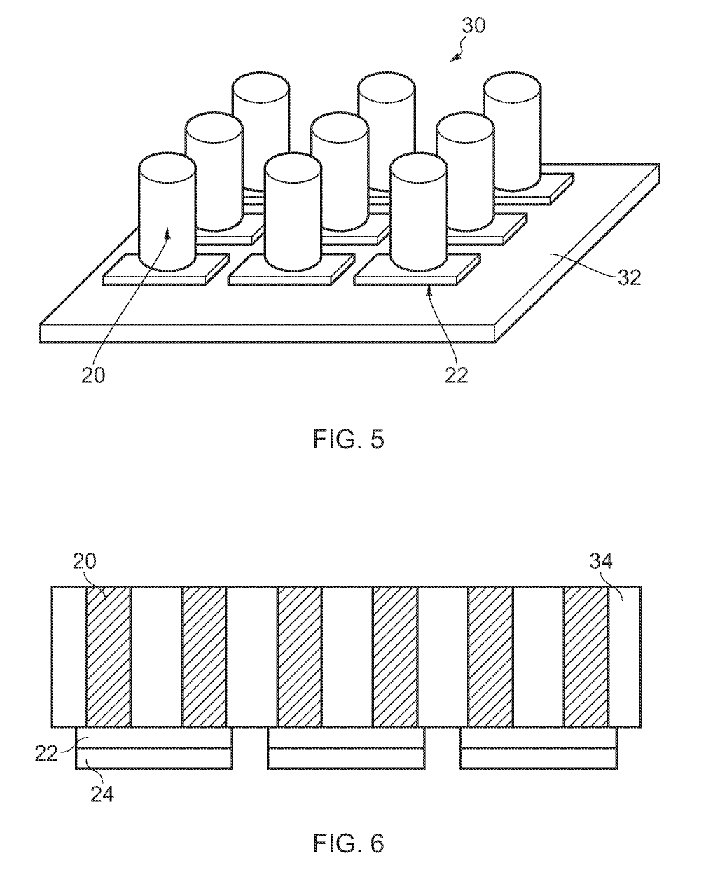

FIG. 5 shows a perspective simplified view of an example of such a data storage device. In this example device 30, nine nanowires 20 are arranged in a regular array of pillars upstanding from a substrate 32. In reality, any number of nanowires can be used, and typically many more than nine will be useful. Each nanowire 20 has an associated data input element 22 at its first, lower end, interposed between the end of the nanowire 20 and the substrate 32. In this example, each data input element comprises a length of current carrying interconnect powered by a CMOS transistor. However, any suitable element capable of injecting domains and therefore domain walls into the end of a nanowire can be used. The magnetic field generated for this purpose by the data input element should be sufficiently localised that domain walls are only formed in the lower end of the associated nanowire pillar, and not further up the nanowire or in an adjacent nanowire.

Alternatively, the data input element may be configured to form domain walls in two or more adjacent nanowires, i.e. the data writing field is not so localised. This may be more convenient than a one-to-one relationship between data input elements and nanowires, for example if the fabrication process causes alignment difficulties in aligning a date input element with a single nanowire. According to this arrangement, several nanowires carry copies of each data bit. This redundancy may be useful.

The device 30 further comprises one or more magnetic field sources (not shown) operable to generate the rotating magnetic field(s) used to propagate the domain walls. Any suitable source or sources may be used, for example magnetic coils placed around the array of pillars 20, a set of micromachined current-carrying wires above the pillars 20, or thick strip lines under the substrate 32. The source(s) should generate a field that extends over the height of the pillars, and covers as many pillars as it is desired to move domain walls in at any one time.

Further, the device 30 comprises a plurality of data read-out elements (not shown), one associated with each pillar 20. The read-out elements can be positioned adjacent to the lower end of the pillars 20 to provide a first-in last-out shift register, as shown in FIG. 4B, or adjacent to the upper end of the pillars to provide a first-in first-out shift register, as shown in FIG. 4A. Alternatively, if it is envisaged that the device might be used sometimes as a first-in first-out register and sometimes as a first-in last-out register, a read-out element can be provided at each end of each pillar.

The read-out elements are operable to sense magnetisation. Associated electronics convert the detected magnetisation into a binary data bit stream, thereby obtaining the data stored in the nanowire. Any suitable type of magnetic sensor can be used. For example, if the read-out elements are positioned at the lower ends of the nanowire pillars, the bottom of each pillar can be configured as the free layer in a magnetic tunnel junction or a giant magnetic resistive spin valve. Alternatively, anisotropic magneto resistance (AMR) can be employed. The read-out elements may be provided such that every data input element has a corresponding read-out element. Alternatively, in an embodiment in which each data input element is associated with more than one nanowire, as discussed above, it may be appropriate to have individual read-out elements for each nanowire. This could take advantage of the redundancy offered by writing each data bit into several nanowires by allowing more detailed error detection and correction.

The nanowire pillars can be fabricated by any of a variety of methods. These include:
standard lithography (deep ultraviolet, optical, electron beam, etc.) with either etching or lift-off to achieve pattern transfer;
nanoimprint lithography; or
templating methods such as anodized aluminium oxide

to produce the required pattern of pillars, followed by depositing the magnetic material using deposition techniques such as:
physical vapour deposition from sputtering, thermal evaporation or electron beam evaporation; or
electrodeposition in solution.

The spiral pattern of the anisotropy easy axis can be achieved by methods such as:
depositing the material on the substrate in the presence of a strong magnetic field with either the substrate or the magnetic field rotating during deposition [11]; or
depositing at a strong angle from the substrate surface normal to create an in-plane anisotropy, with rotation of either the substrate or the deposition source.

Any magnetic material that can be formed into nanowires with the required anisotropy and which allow the formation and propagation of domain walls may be used for the nanowires. A soft material allows easier propagation of the domain walls. Also, a material with suitable nucleation and propagation fields such that the magnetic fields for data input and for domain wall propagation can be conveniently achieved while keeping the two effects distinct (i.e. the values of the nucleation field and of the propagation field are sufficiently separated from one another) is beneficial. Typical examples of suitable materials include permalloy (NiFe), supermalloy (NiFeMo), CoFeB, CoFe, cobalt (Co), iron (Fe) and nickel (Ni).

As an alternative to providing the nanowires as pillars upstanding from a substrate, the nanowires may instead be plugs of magnetic material filling (wholly or partially) pores or holes in a substrate. The substrate may be, for example, anodic aluminium oxide, but other suitable non-magnetic materials in which appropriately sized pores can be fabricated may be employed. In anodic aluminium oxide, the pores are already present. In other materials pores may be fabricated using a conventional patterning technique such as lithography or templating. The magnetic material can then be introduced into the pores using a deposition technique such as electrodeposition. An advantage of this configuration is that the nanowires are protected from damage as compared to free-standing pillars on a substrate, which are much more exposed. However, formation of the spiralling of the locus of the easy axis of the anisotropy may be found to be more complex than for a pillar arrangement.

FIG. 6 shows a cross-sectional view through a device having nanowires formed as plugs of magnetic material. Six nanowires 20 are shown, in the form of magnetic material filling pores in a substrate 34. In this example, the data input elements 22 and the data read-out elements 24 are both at the same ends of the nanowires, providing a first-in last-out shift register. Also, each element is associated with two nanowires 20. However, the elements may each be associated with a single nanowire, or with more than two nanowires, as discussed above regarding the embodiment of FIG. 5. The embodiment of FIG. 6 shows the nanowires extending through the full width of the substrate. This gives access to both ends of the nanowires, so both first-in first-out and first-in last-out shift registers can be achieved. However, in other examples the pores may penetrate only partially through the substrate. This gives only one exposed end of each nanowire, suitable for a first-in last-out register.

Estimates of the potential data storage capacity of devices according to embodiments of the invention can be made to demonstrate the potential improvement over current solid-state semiconductor non-volatile memory. In the following examples, the storage density is expressed in Gbits/inch², which is the figure of merit used by the hard disk drive industry. To allow comparison between the three-dimensional storage offered by the invention and the planar two-dimensional storage of semiconductor memory and hard disks, all the bits storable in the spiral height of a nanowire column of the invention are considered as being concentrated onto the footprint of the spiral. This converts a volumic storage density into an effective areal storage density. Current state of the art storage density for hard disk drives is about 200 Gbits/inch², while that for Flash memory is about 10 Gbits/inch².

### Example 1

300 nm diameter pillars arranged on a substrate in a 350 nm square pitch. Each pillar is 3 μm high, and the pitch of the anisotropy spiral is 100 nm. These dimensions represent conservative values for the capability for lithography (current state of the art lithography resolution being 45 nm). The spiral pitch is selected so that it is not less than the width of a domain wall for the anisotropy of the magnetic material (so that the domain walls are properly separated for correct propagation along the spiral by the rotating magnetic field); in this example the pitch is approximately equal to the wall width, although a bigger pitch may be optimum. These values give an effective areal density of 160 Gbits/inch², which is 16 times higher than the current state of the art for Flash memory even though the selected values are conservative.

### Example 2

Magnetic material in anodic aluminium oxide pores, the pores on a 200 nm square pitch. However, to avoid any alignment difficulties, the data input and read-out elements are 1 μm², so that each addresses multiple nanowires (thereby reducing the data density). The pores are 1 mm in height, and the pitch of the anisotropy spiral is 50 nm. This gives an effective areal density of 13,000 Gbits/inch², vastly superior to the state of the art for either hard disk drives or Flash memory.

Thus, it can be seen that the present invention offers great potential for offering improvements in data storage.

The term “nanowire” is used throughout this specification and the appended claims. However, it is not intended that the invention be limited to structures of magnetic material with dimensions that strictly comply with this term. Any magnetic material structure having dimensions that allow formation and propagation of domain walls in the described manner is intended to be included, even those structures with dimensions which might be interpreted as taking the structure outside a strict definition of “nanowire”, for example structures which might be more conventionally referred to as “microwires”. For example, in some possible implementations of the present invention, “nanowires” may include wires having a diameter of around or less than 1 nm, around or less than 10 nm, around or less than 100 nm, or around or less than 300 nm.

Also, data storage devices in accordance with the present invention are not limited to the configurations described and illustrated herein. Alternative configurations that nonetheless fall within the scope of the appended claims can be readily envisaged.

1. A data storage device comprising:
at least one wire of magnetic material having an anisotropy with an easy axis substantially perpendicular to the longitudinal axis of the wire and which is rotated about the longitudinal axis along the length of the wire, wherein the wire is a nanowire or microwire;
each of the at least one wires having associated therewith:
a data input element operable to nucleate magnetic domains in an end of the wire, the domains separated by domain walls substantially perpendicular to the longitudinal axis of the wire; and
a data read-out element operable to detect the magnetisation at an end of the wire; and
a magnetic field source operable to generate a rotating magnetic field over the length of the at least one wire, the magnetic field rotating in a plane substantially perpendicular to the longitudinal axis of the at least one wire so as to propagate domain walls along the at least one wire.

2. The device of claim 1, wherein the magnetisation state follows the easy axis except if a domain wall is present.

3. The device of claim 1, wherein the magnetic field source is arranged to match the rotation sense of the rotating magnetic field to the rotation sense of locus of the easy axis of the anisotropy.

4. A data storage device according to claim 1, in which the at least one wire comprises a plurality of wires with parallel longitudinal axes.

5. A data storage device according to claim 4, in which each wire comprises a pillar of magnetic material upstanding from a substrate.

6. A data storage device according to claim 5, in which each data input element comprises a current-carrying electrode interposed between the pillar and the substrate.

7. A data storage device according to claim 4, in which each wire comprises a plug of magnetic material in a pore formed in a substrate.

8. A data storage device according to claim 1, in which each data read-out element is arranged at the opposite end of its associated wire to the data input element, to provide a first-in first-out shift register.

9. A data storage device according to claim 1, in which each data read-out element is arranged at the same end of its associated wire as the data input element, to provide a first-in last-out shift register.

10. A data storage device according to claim 9, in which the magnetic field source is operable such that the direction of rotation of the magnetic field can be reversed.

11. A data storage device according to claim 1, in which each data input element is associated with only one wire.

12. A data storage device according to claim 1, in which each data input element is associated with more than one wire.

13. A method of storing data, comprising:
applying a magnetic field to a first end of a wire of magnetic material to nucleate a sequence of magnetic domains separated by domain walls in the end of the wire, the sequence being selected to represent a chosen binary bit stream of data, where the wire has an anisotropy with an easy axis substantially perpendicular to the longitudinal axis of the wire and which is rotated about the longitudinal axis along the length of the wire; and
applying a rotating magnetic field over the length of the wire, the magnetic field rotating in a plane substantially perpendicular to the longitudinal axis of the wire so as to propagate the domain walls along the wire;
wherein the wire is a nanowire or microwire.

14. The method of claim 13, wherein the magnetisation state follows the easy axis except if a domain wall is present.

15. The method of claim 13, wherein the applying comprises matching the rotation sense of the rotating magnetic field to the rotation sense of locus of the easy axis of the anisotropy.

16. A method according to claim 13, further comprising:
using the rotating magnetic field to propagate the domain walls to the second end of the wire; and
reading out the bit stream of data by detecting the magnetisation of the second end of the wire as the domains and domain walls arrive at the second end.

17. A method according to claim 13, further comprising:
reversing the direction of rotation of the rotating magnetic field and using the reversed rotating magnetic field to propagate the domain walls back the first end of the wire; and
reading out the bit stream of data by detecting the magnetisation of the first end of the wire as the domains and domain walls arrive at the first end.

18. A method of fabricating a data storage device, comprising:
forming at least one wire of magnetic material by depositing magnetic material in or on a substrate so as to create an anisotropy in the magnetic material which has an easy axis substantially perpendicular to the longitudinal axis of the wire and which is rotated about the longitudinal axis along the length of the wire, wherein the wire is a nanowire or microwire;
providing in association with each of the at least one wires:
data input element operable to nucleate magnetic domains in an end of the wire; and
data read-out element operable to detect the magnetisation at an end of the wire; and
providing a magnetic field source operable to generate a rotating magnetic field over the length of the at least one wire, the magnetic field rotating in a plane substantially perpendicular to the longitudinal axis of the at least one wire so as to propagate domain walls along the at least one wire.

19. The method of claim 18, wherein the magnetisation state in the magnetic material follows the easy axis except if a domain wall is present.

20. The method of claim 18, further comprising arranging the magnetic field source to be operable to match the rotation sense of the rotating magnetic field to the rotation sense of locus of the easy axis of the anisotropy.

21. A method according to claim 18, in which the forming the at least one wire comprises forming a plurality of wires with parallel longitudinal axes.

22. A method according to claim 18, in which each of the at least one wire is formed as a pillar upstanding from the substrate.

23. A method according to claim 22, in which the anisotropy is created by depositing the magnetic material on the substrate in the presence of a magnetic field during relative rotation between the substrate and the magnetic field.

24. A method according to claim 22, in which the anisotropy is created by depositing the magnetic material from a deposition source onto the substrate at a strong angle from the normal to the substrate surface during relative rotation between the substrate and the deposition source.

25. A method according to claim 23, in which each of the at least one wires is formed as a plug of magnetic material within a pore in the substrate.

26. A method according to claim 18, in which providing a data read-out element comprises arranging each data read-out element at the opposite end of its associated wire to the data input element, to provide a first-in first-out shift register.

27. A method according to claim 18, in which providing a data read-out element comprises arranging each data read-out element at the same end of its associated wire as the data input element, to provide a first-in last-out shift register.

28. A method according to claim 18, in which providing a data input element comprises associating the or each data element with only one wire.

29. A method according to claim 18, in which providing a data input element comprises associating the or each data element with more than one wire.
